(19) United States
(12) Patent Application Publication
(10) Pub. No.: US 2023/0386997 A1
(43) Pub. Date: Nov. 30, 2023

(54) SEMICONDUCTOR DEVICES WITH REDUCED EFFECT OF CAPACITIVE COUPLING

(71) Applicant: Taiwan Semiconductor Manufacturing Company, Ltd., Hsinchu (TW)

(72) Inventors: Chih-Yu Lu, Hsinchu County (TW); Chih-Yu Lai, Hsinchu County (TW); Meng-Hsueh Wang, Hsinchu County (TW); Chih-Liang Chen, Hsinchu County (TW); Shang Hsuan Chiu, Hsinchu County (TW)

(73) Assignee: Taiwan Semiconductor Manufacturing Company, Ltd., Hsinchu (TW)

(21) Appl. No.: 17/825,698

(22) Filed: May 26, 2022

(51) Int. Cl. H01L 23/522; H01L 23/528; H01L 29/40; H01L 29/417; H01L 27/088; H01L 21/8234

(52) U.S. Cl. CPC H01L 23/5225; H01L 23/5226; H01L 23/5283; H01L 23/5286; H01L 29/401; H01L 29/41775; H01L 27/088; H01L 21/823475; H01L 29/41791; H01L 27/0886

(57) ABSTRACT

A semiconductor device includes a first source/drain structure and a second source/drain structure of a first transistor. The semiconductor device includes a first source/drain structure and a second source/drain structure of a first transistor. The semiconductor device includes a third source/drain structure and a fourth source/drain structure of a second transistor. The second source/drain structure and the third source/drain structure merges as a common source/drain structure. The semiconductor device includes a first interconnect structure extending along a first lateral direction and disposed above the common source/drain structure. The semiconductor device includes a first dielectric structure interposed between the first interconnect structure and the common source/drain structure.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a circuit diagram of an example circuit and its corresponding layout design, in accordance with some embodiments.

FIG. 1B illustrates a cross-sectional view of an example semiconductor device made based on the layout design of FIG. 1A, in accordance with some embodiments.

FIG. 1C illustrates a cross-sectional view of another example semiconductor device made based on the layout design of FIG. 1A, in accordance with some embodiments;

FIG. 2 illustrates a circuit diagram with a corresponding layout design and cross-sectional views of another example semiconductor device, in accordance with some embodiments;

FIG. 3 illustrates a circuit diagram with a corresponding layout design of an example NAND2 device, in accordance with some embodiments;

FIG. 4 illustrates a circuit diagram with a corresponding layout design of an example AOI22 device, in accordance with some embodiments;

FIG. 5 illustrates a circuit diagram with a corresponding layout design of an example NAND3 device, in accordance with some embodiments;

FIG. 6 illustrates a circuit diagram with a corresponding layout design of an example inverter, in accordance with some embodiments; and

FIG. 7 illustrates a flow diagram of an example method for forming a semiconductor device including a dielectric structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

With two or more transistors connected in series, respective source/drain structures of those serially connected transistors can share a common node. Such a common node is sometimes referred to as an internal node or a series node, which is generally not connected to the input, output, or a power supply voltage of a corresponding circuit. In consideration of minimizing a total area that the circuit occupies, the common node is generally interposed or positioned between the gate structures of these serially connected transistors. Even without connecting to any input, output, or power supply voltage, the common node is still overlaid by an interconnect structure that is concurrently formed with other interconnect structures configured to electrically route other (e.g., output) nodes of the circuit. However, coupling between this interconnect structure connected to the common node and neighboring gate structures (e.g., through one or more parasitic capacitance) may interfere with signals applied to those gate structures, which are commonly sensitive or critical to the circuit (e.g., input signals, clock signals, etc.), and/or signals present on the common node, which can in turn interfere with corresponding transistors. The increase in such capacitive coupling can negatively impact the overall performance of the circuit such as, for example, voltage level fluctuation, signal interference, among others. Hence, the existing techniques for forming interconnect structures of a semiconductor device or circuit have not been entirely satisfactory in many aspects.

The present disclosure provides various embodiments of a semiconductor device that can be formed to minimize or avoid an effect of capacitive coupling between its gate structure(s) and interconnect structure(s) connected to common node(s). For example, the semiconductor device can include a number of transistors (e.g., a first transistor, a second transistor, etc.), each of which includes a respective gate structure and source/drain structures. The transistors can share a common source/drain structure between the gate structures. The semiconductor device can include the interconnect structure disposed above and connected to the common source/drain structure. To minimize the capacitive coupling between the interconnect structure and other neighboring conductive structures (e.g., the gate structures interposing the interconnect structure), the semiconductor device can include a dielectric structure (e.g., isolation layer) interposed between the interconnect structure and the common source/drain structure, thereby isolating the interconnect structure, which may be at a floating voltage, from the common source/drain structure. As such, even if there is coupling between the interconnect structure and neighboring gate structures, a signal (e.g., voltage) level at the common node will not interfere with signals present on the neighboring gate structures. Further, with the dielectric structure interposed between the common node and its corresponding interconnect structure, the interconnect structure is electrically isolated from the common node. As such, the interconnect structure can be tied to a power supply voltage or a constant voltage, which may advantageously resist noise and/or stable the signals present on the neighboring gate structures.

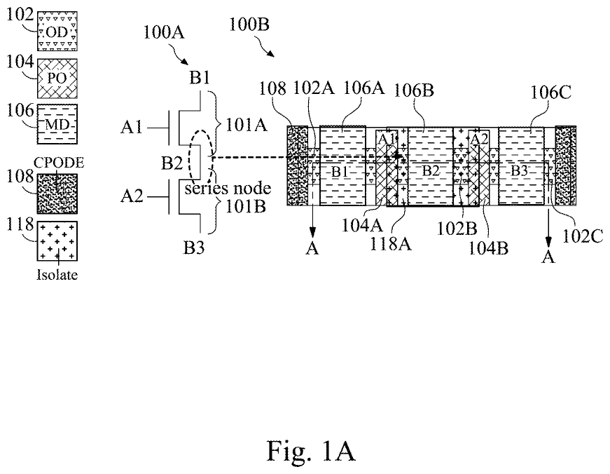

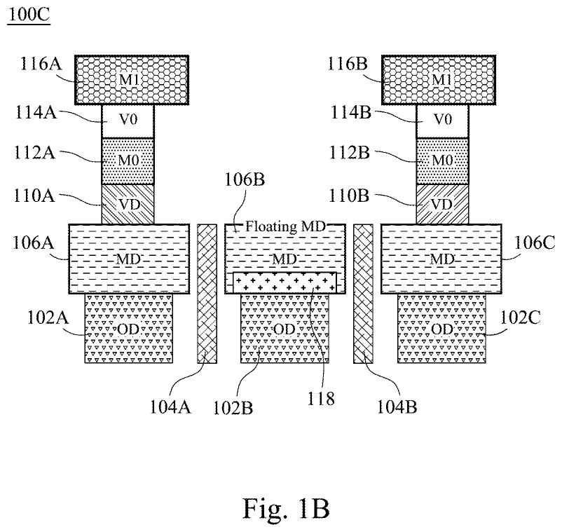

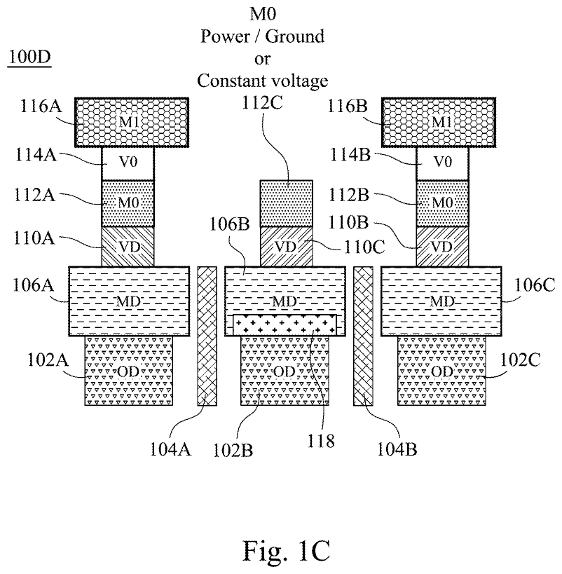

Referring first to FIG. 1A, a circuit diagram of an example circuit 100A and a corresponding layout design 100B of a portion of the example circuit 100A are depicted, in accordance with various embodiments. The circuit 100A includes a first transistor 101A and a second transistor 101B connected to each other in series. As such, a gate (A1) and a first source/drain (B1) of the first transistor 101A, and a gate (A2) and a first source/drain (B3) of the second transistor 101B can be coupled to or formed as conductive structures, respectively, with a second source/drain of the first transistor 101A and a second source/drain of the second transistor 101B connected to a common node (B2).

As shown in FIG. 1A, the layout 100B includes patterns 102, 104A, 104B, and 108. The pattern 102 is configured to form or otherwise define an active region (sometimes referred to as an oxide-diffusion/definition (OD)) over a substrate, and thus, the pattern 102 is hereinafter referred to as OD 102. The patterns 104A and 104B are configured to form a number of gate structures, and thus, the patterns 104A and 104B are hereinafter referred to as gate structures 104A and 104B, respectively. The pattern 108 is configured to form an isolation structure (sometimes referred to as a cut-poly-OD-edge (CPODE)) disposed along an edge of the OD 102, and thus, the pattern 108 is hereinafter referred to as CPODE 108.

In various embodiments, the OD 102 can extend along a first lateral direction (e.g., shown as horizontal in FIG. 1A), and the gate structures 104A-B can each extend along a second lateral direction (e.g., shown as vertical in FIG. 1A). As such, the gate structures 104A and 104B can each traverse or otherwise overlay a respective portion of the OD 102, which forms the conductive channel of a corresponding transistor, with other non-overlaid portions of the OD 102 each formed as a source/drain structure of the corresponding transistor. For example, the gate structure 104A can form the gate A1 of the transistor 101A and the gate structure 104B can form the gate A2 of the transistor 101B, with portion 102A located on a left-hand side of the gate structure 104A formed as the source/drain B1 of the transistor 101A and portion 102C located on a right-hand side of the gate structure 104B formed as the source/drain B3 of the transistor 101B, respectively. Further, portion 102B interposed between the gate structures 104A and 104B can correspond to the common node B2, which is formed as a merged or otherwise shared source/drain structure.

In various embodiments, the layout 100B of FIG. 1A can be utilized to form the circuit 100A constituted by the transistors 101A and 101B. The transistors can be implemented as any of various types of transistors such as, for example, planar transistors, fin-based transistors (sometimes referred to as FinFETs), nanostructure transistors (sometimes referred to as gate-all-around (GAA) transistors), etc. In the example where the transistors 101A and 101B are formed as FinFETs, the OD 102 may be originally formed as a fin protruding from a substrate, where the portions of the fin overlaid (or straddled) by the gate structures 104A and 104B are configured as the channels of the transistors 101A and 101B, and the portion of the fin non-overlaid (or straddled) by the gate structures 104A and 104B are later removed and (e.g., epitaxially) regrown as the source/drains of the transistors 101A and 101B, respectively. The gate structures 104A-B of the FinFETs can modulate (e.g., turn on or off) current conducting from their sources, through their channels, and to their drains, respectively. Such functional structures of a transistor (and other active devices, for example, resistors, capacitors, etc.) are collectively referred to as front-end-of-line (FEOL) structures.

Referring still to FIG. 1A, the layout 100B further includes a number of patterns 106A, 106B, and 106C configured to form interconnect structures (e.g., source/drain interconnect structures) disposed above and connected to the non-overlaid portions (source/drain structures) 102A, 102B, and 102C, respectively. These source/drain interconnect structures are sometimes referred to as MDs, and thus, the patterns 106A to 106C are hereinafter referred to as MDs, 106A, 106B, and 106C, respectively. The MDs 106A to 106C may each extend in parallel with a lengthwise direction of the gate structures 104A-B, in some embodiments. These MDs 106A to 106C are typically formed over the FEOL structures, which may form part of the middle-end-of-line (MEOL) structures. In some implementations, the MDs 106A to 106C can include a conductive material such as, for example, one or more metal materials. As will be discussed below in FIGS. 1B and 1C, a number of structures (e.g., metal structures or metallization layers) can be formed over the MEOL structures to operatively (e.g., electrically) connect those FEOL/MEOL structures, thereby enabling the intended functionality of the circuit 100A. These metal structures are collectively referred to as back-end-of-line (BEOL) structures.

In accordance with various embodiments, the layout 100B further includes a pattern 118 configured to form an isolation layer. Hereinafter, the pattern 118 is referred to as isolation layer 118. The isolation layer 118 can be disposed over the portion 102B (e.g., the common node B2 shown in the circuit diagram, or the merged source/drain structure as described above). For example in the layout 100B of FIG. 1A, the isolation layer 118 can laterally extend from the gate structure 104A to gate structure 104B (e.g., extending laterally beyond two edges of the portion 102B connected to the gate structures 104A and 104B, respectively), with a vertical extension extending vertically beyond other two edges of the portion 102B. As shown, the isolation layer 118 has a rectangular profile. However, it should be understood that the isolation layer 118 can be formed in any of various other profiles (as long as it can fully overlay the portion 102B) while remaining within the scope of the present disclosure. The isolation layer 118 is formed of a dielectric material. As a result, with the portion 102B fully overlaid by the isolation layer 118, the MD 106B can be electrically isolated from the portion 102B.

Referring next to FIG. 1B, a cross-sectional view of a semiconductor device 100C formed based on the layout 100B of FIG. 1A is shown, in accordance with various embodiments. The cross-sectional view of FIG. 1B is cut along line A-A of FIG. 1A. For the sake of clarity, some of the structures in the layout 100B may not be shown, while some other structures (e.g., VD 110A-B, M0 112A-B, VO 114A-B, and M1 116A-B), which are not illustrated in the layout 100B, are shown in FIG. 1B.

As shown, above the source/drain structures 102A-C, respective interconnect structures can be formed, such as the MD 106A above the source/drain structure 102A, the MD 106B above the source/drain structure 102B, and the MD 106C above the source/drain structure 102C. In various embodiments, the MD 106A is in (e.g., electrical) contact with the source/drain structure 102A, the MD 106C is in (e.g., electrical) contact with the source/drain structure 102C, and the MD 106B is in (e.g., electrical) isolation from the source/drain structure 102B through the isolation layer 118. Further, above the MDs 106A and 106C, other interconnect structures can be formed, such as at least M0 112A and M1 116A above MD 106A, and M0 112B and M1 116B above MD 106C. The M0 112A is in (e.g., electrical) contact with the MD 106A through VD 110A, and the M1 116A is in (e.g., electrical) contact with the M0 112A through VO 114A. Similarly, the M0 112B is in (e.g., electrical) contact with the MD 106C through VD 110B, and the M1 116B is in (e.g., electrical) contact with the M0 112B through VO 114B. Structures VDs 110A and 110B, MOs 112A and 112B, VOs 114A and 114B, and M1s 116A and 116B are part of the above-mentioned BEOL structures.

To minimize the effect of capacitive coupling between the MD 106B and the gate structure 104A and/or between the MD 106B and the gate structure 104B, the isolation layer 118 is interposed between the MD 106B and the OD portion 102B. In some embodiments, the isolation layer 118 is disposed above and fully overlays the OD portion 102B. As such, the MD 106B is electrically isolated from the OD portion 102B, and any signal (e.g., unintentionally) present on the MD 106B can be “blocked out” from the OD portion 102B, which will not affect normal operation of the semiconductor device 100C. For example, the MD 106B (without connecting to any other BEOL structures as shown in FIG. 1B) may present a floating voltage. Even if there is coupling between the MD 106B and the adjacent gate structures 104A and/or 104B, a signal level present at the OD portion 102B will not be affected. In some implementations, the isolation layer 118 can be a part of the MD 106B, such as a layer embedded in the MD 106B. In some other implementations, the isolation layer 118 can be an additional layer above the OD portion 102B.

Referring next to FIG. 1C, a cross-sectional view of another semiconductor device 100D formed based on the layout 100B of FIG. 1A is shown, in accordance with various embodiments. The cross-sectional view of FIG. 1C is cut along line A-A of FIG. 1A. For the sake of clarity, some of the structures in the layout 100B may not be shown, while some other structures (e.g., VD 110A-C, M0 112A-C, VO 114A-B, and M1 116A-B), which are not illustrated in the layout 100B, are shown in FIG. 1C.

As shown, in addition to the structures of the semiconductor device 100C of FIG. 1B, above the MD 106B, one or more other interconnect structures can be formed, such as at least M0 112C. The M0 112C is in (e.g., electrical) contact with the MD 106B through VD 110C. Accordingly, structures M0 112B and VD 110C are also part of the above-mentioned BEOL structures and MEOL structures, respectively, such as in addition to the structures described above. In some implementations, M0 112C can correspond to or be connected to a power supply voltage (e.g., VDD, VSS (or ground), etc.), such that electricity can be supplied to MD 106B or the MD 106B can be grounded. In some other implementations, through the VD 110C, the MD 106B can connect to a constant voltage, thereby stabilizing sensitive signals from each of the gate structures and/or reducing the resistance of long PO 104 (e.g., greater than or equal to two cell rows) parallel to the MD 106B. In another example, by connecting MD 106B to ground, a shielding net can be formed to reduce or resist noise from interfering with input signals from the gate structures. Accordingly, with the dielectric structure in the design and coupling the MD 106B to a source or ground, capacitive coupling can be minimized or avoided without additional masking layers, changes to the cell floorplan and routing, and extra routing resources.

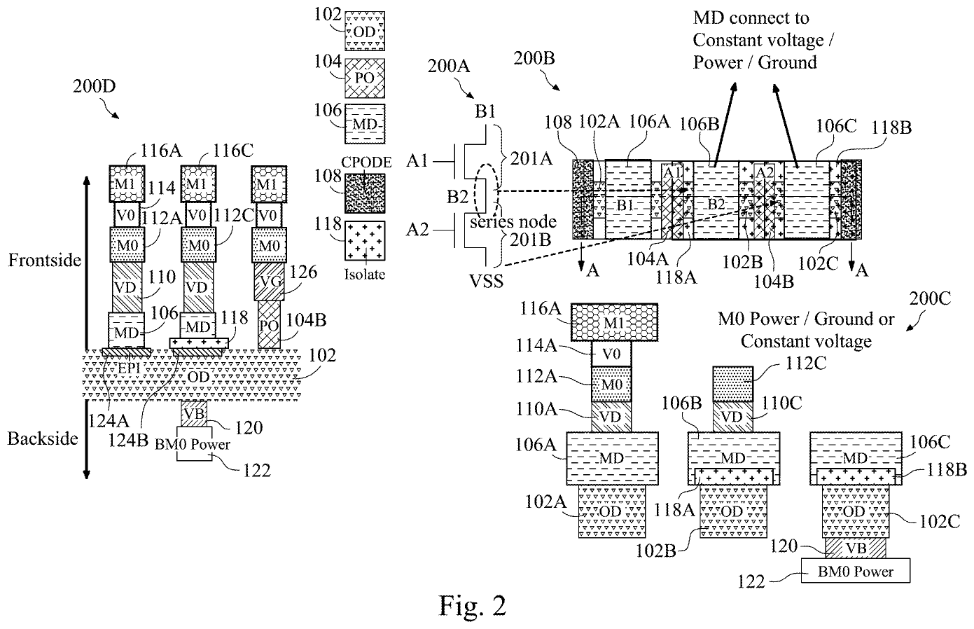

Referring to FIG. 2, a circuit diagram of another example circuit 200A and a corresponding layout design 200B of a portion of the example circuit 200A, and cross-sectional views of semiconductor device 200C and semiconductor device 200D are depicted, respectively, in accordance with various embodiments. The circuit 200A can include one or more features similar to circuit 100A, such as the source/drain B1 and a common source/drain B2. Additionally or alternatively, the second source/drain structure (e.g., B3 of circuit 100A) can be (e.g., electrically) connected to a power source (e.g., VSS).

As shown in FIG. 2, layout 200B includes one or more patterns similar to the layout 100B, such as patterns 102A-C, 104A-B, 106A-C, 108, and 118. The isolation layer 118 shown in layout 100B can correspond to the isolation layer 118A (e.g., a first isolation layer or a first dielectric structure). In accordance with various embodiments, the layout 200B further includes a pattern 118B configured to form another isolation layer. Hereinafter, the pattern 118B is referred to as an isolation layer 118B (e.g., a second isolation layer or a second dielectric structure). The isolation layer 118B can be disposed over the portion 102C (or over portion 102A, among other non-overlaid portions of the OD 102). The isolation layer 118B can include or be composed of similar or different dielectric materials as the isolation layer 118A. The isolation layer 118B can laterally extend from the gate structure 104B to the CPODE 108 (e.g., extending laterally beyond two edges of the portion 102C connected to the gate structure 104B and the CPODE 108, respectively), with a vertical extension extending vertically beyond other two edges of the portion 102C. A similar isolation layer can be disposed at portion 102A, such as in addition to portions 102B and 102C, or instead of portion 102C of this example.

Still referring to FIG. 2, as shown in a cross-sectional view of the semiconductor device 200C formed based on the layout 200B is shown. The cross-sectional view is cut along line A-A of FIG. 2. For the sake of clarity, some of the structures in the layout 200B (e.g., gate structures 104A, 104B) are not shown, while some other structures (e.g., VDs 110A and 110B, MOs 112A and 112C, VO 114A, M1 116A, VB 120, and BMO 122), which are not illustrated in the layout 200B, are shown in this cross-sectional view.

One or more structures of the semiconductor device 200C can be similar to the structures of semiconductor device 100C. For example, above the source/drain structures 102A-C, respective interconnect structures can be formed, such as the MD 106A above the source/drain structure 102A, the MD 106B above the source/drain structure 102B, and the MD 106C above the source/drain structure 102C. Further, above the MDs 106A and 106B, other interconnect structures can be formed, such as at least M0 112A and M1 116A above MD 106A, and M0 112C above MD 106C, among other parts of the BEOL structure. In various embodiments, the MD 106A is in (e.g., electrical) contact with the source/drain structure 102A, the MD 106B is in (e.g., electrical) isolation from the source/drain structure 102B through the isolation layer 118A, and the MD 106C is in (e.g., electrical) isolation from the source/drain structure 102C through the isolation layer 118B.

As shown in the cross-sectional view of the semiconductor device 200C, one or more interconnect structures can be formed on the backside of the substrate. For example, below at least one source/drain structure, respective interconnect structures can be formed, such as the BMO 122 (e.g., backside M0) below the source/drain structure 102C. Although the backside interconnect structure is shown for source/drain structure 102C, it should be understood that backside interconnect structures can be formed in any of various other source/strain structures (e.g., source/drain structures 102A and/or 102B) while remaining within the scope of the present disclosure. In various embodiments, the BMO 122 is in (e.g., electrical) contact with the MD 106C through VB 120 (e.g., backside via structure). For instance, the VB 120 can route the BMO 122 to MD 106C, thereby enabling (e.g., electrical) contact between the MD 106C and BMO 122. In some cases, BMO 122 can provide power (e.g., constant voltage) to the MD 106C.

Still referring to FIG. 2, the cross-sectional view of the semiconductor device 200D formed based on the layout 200B of FIG. 2 is shown. This cross-sectional view of is cut along line A-A of FIG. 2. For the sake of clarity, some of the structures in the layout 200B (e.g., gate structure 104A, MD 106C, and isolation layer 118B) are not shown, while some other structures (e.g., VD 110, MOs 112A and 112C, VO 114, M1s 116A and 116C, VB 120, and BMO 122), which are not illustrated in the layout 200B, are shown in this cross-sectional view.

As shown, this cross-sectional view includes patterns 124A and 124B. The patterns 124A and 124B are configured to form or otherwise define respective EPIs at portions of the OD 102, thus the patterns 124A and 124B are hereinafter referred to as EPI 124A and EPI 124B, respectively. For example, the EPI 124A can correspond to or be a part of OD portion 102A, and the EPI 124B can correspond to or be a part of OD portion 102B. The EPIs 124A and 124B can form or otherwise define the source/drain structure of the semiconductor device 200D. For instance, the EPIs 124A and 124B can be parts of the non-overlaid portions of the OD 102, each formed as a respective source/drain structure of the corresponding transistor. In this case, the EPI 124A can correspond to source/drain B1 and EPI 124B can correspond to the common node B2 (e.g., the shared source/drain structures between the first and second transistors (e.g., respectively 201A and 201B of circuit 200A).

In various implementations, above the one or more gate structures, respective interconnect structures can be formed. Although the gate structure 104B is shown to include the interconnect structures, other gate structures (e.g., gate structure 104A) can include the respective interconnect structures. For example, M0 112 can be disposed above the gate structure 104B (or another gate structure), and M1 116 can be disposed above the M0 112. The M0 112 is in (e.g., electrical) contact with the gate structure 104B through VG 126, and the M1 116 is in (e.g., electrical) contact with the M0 112 through VO 114.

Further, the semiconductor device 200D can include one or more interconnect structures on the backside of the substrate. As shown, BMO 122 can be disposed on a portion of the backside of the OD 102, such as a backside portion of OD portion 102B, among other portions. In reference to semiconductor device 200C, the backside interconnect structure can be in (e.g., electrical) connection with MD 106C (e.g., not shown in semiconductor device 200D). Additionally or alternatively, the backside interconnect structure(s) or other backside interconnect structures can be in (e.g., electrical) connection with MD 106A or MD 106B, for example.

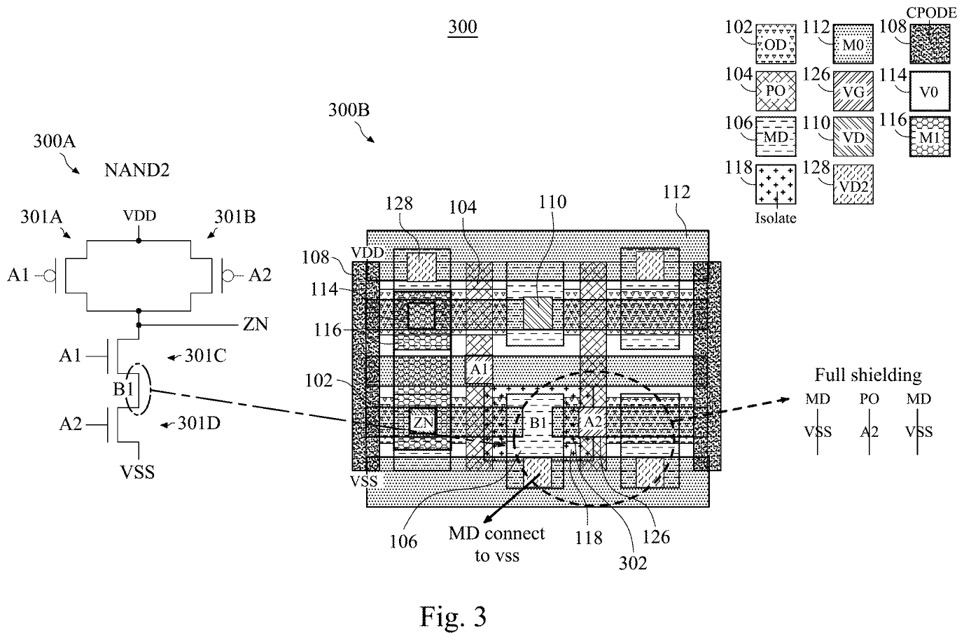

Referring to FIG. 3, a circuit diagram of an example circuit 300A and a corresponding layout design 300B of a portion of the example circuit 300A are depicted, in accordance with various embodiments. The circuit 300A and the layout design 300B can correspond to a NAND2 device. The circuit 300A includes a first transistor 301A, a second transistor 301B, a third transistor 301C, and a fourth transistor 301D connected to each other either in parallel or in series. The circuit 300A and the layout 300B can include one or more structures or features similar to, as part of, or in addition to circuit 100A or layout designs 100B and/or 200B. The circuit 300A can include a series connection between the third transistor 301C and the fourth transistor 301D (e.g., similar to the first transistor 101A and the second transistor 101B of circuit 100A in conjunction with FIG. 1A). For example, the third transistor 301C and the fourth transistor 301D can share a common node (B1) (e.g., a common source/drain), such as similar to the common node B2 of FIGS. 1-2.

As shown in FIG. 3, the layout 300B includes one or more patterns similar to one or more patterns associated with layouts 100B and/or 200B of FIGS. 1-2. The patterns can be configured to form or otherwise define respective structures or components, as described herein. For example, the OD 102 can represent the active region, the PO 104 can represent the gate structure 104, etc. In various embodiments, the gates A1 and A2 can each traverse or otherwise overlay a respective portion of the OD 102, which forms the conductive channel of a corresponding transistor, with other non-overlaid portions of the OD 102 each formed as a source/drain structure of the corresponding transistor. Each gate of layout 300B can be formed or disposed across different cell rows or transistors. For example, the gate A1 can be formed for the first transistor 301A and the third transistor 301C, and the gate A2 can be formed for the second transistor 301B and the fourth transistor 301D at respective portions of the OD 102.

Further, the patterns can include, for example, interconnect structures disposed above and connected to the portions of the OD 102 or the gate structures 104 (e.g., gates A1 and A2). For example, above the portions of the OD 102 (or the source/drain structures), respective interconnect structures can be formed, such as the MD 106 above the source/drain structure 302, among other MDs 106. Other interconnect structures can be disposed above one or more MDs 106 and gate structures 104. For example, the MOs 112 are disposed above one or more MDs 106, and M1s 116 are disposed above one or more MOs 112. The MD 106 can be in (e.g., electrical) contact with the M0 112 through VD 110. The M0 112 can be in (e.g., electrical) contact with the M1 116 via VO 114. Further, one or more MOs 112 is in (e.g., electrical) contact with the CPODE 108 (e.g., a power source or power rail). The MD 106 can be in (e.g., electrical) contact with the M0 112 to receive power through VD2 128. In some cases, the MD 106 can be connected to ground through at least one of the via structures (e.g., VD 110, VD2 128, etc.). Additionally, the gate structures 104 can be in (e.g., electrical) contact with at least one interconnect structure, such as M0 112 through VG 126.

In layout 300B, to minimize the effect of capacitive coupling between the MD 106 (e.g., above the common node B1) and the gate A1 and/or between the MD 106 and the gate A2, the isolation layer 118 is interposed between the MD 106 and the OD portion 302. In some embodiments, the isolation layer 118 is disposed above and fully overlays the OD portion 302. As such, the MD 106 is electrically isolated from the OD portion 302. In some implementations, other MDs 106 can be electrically isolated from their respective portions of the OD 102 (e.g., or isolated from the respective source/drain structures) by interposing the isolation layer 118 between the MDs 106 and the OD portions.

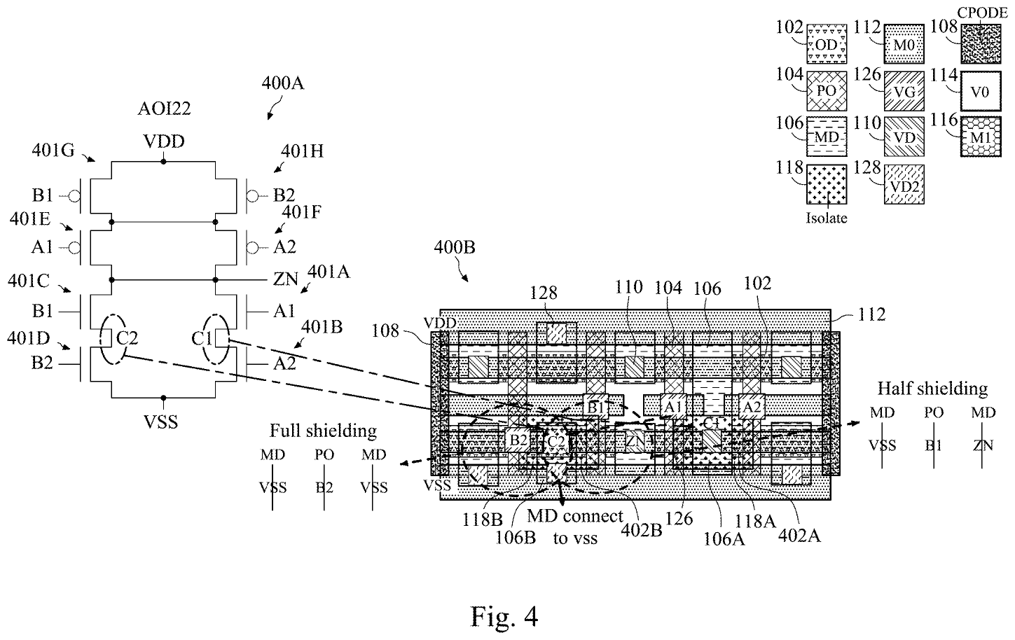

Referring next to FIG. 4, a circuit diagram of an example circuit 400A and a corresponding layout design 400B of a portion of the example circuit 400A are depicted, in accordance with various embodiments. The circuit 400A and the layout design 400B can correspond to an AOI22 device. One or more structures, formations, or dispositions of AOI22 can be described similarly to the semiconductor device of FIGS. 1-3, for example. The circuit 400A includes a first transistor 401A, a second transistor 401B, a third transistor 401C, a fourth transistor 401D, a fifth transistor 401E, a sixth transistor 401F, a seventh transistor 401G, and an eighth transistor 401H connected to each other either in parallel or in series. For example, the first transistor 401A connects to the second transistor 401B in series, and the third transistor 401C connects to the fourth transistor 401D in series. In this example, transistors 401A and 401B share a first common node (C1) and transistors 401C and 401D share a second common node (C2).

As shown in FIG. 4, the layout 400B includes one or more patterns (e.g., forming or defining OD 102, PO 104, MD 106, etc.) similar to one or more patterns associated with layouts of FIGS. 1-3. In various embodiments, the layout 400B includes four gate structures 104, such as gates A1, A2, B1, and B2. The gates can traverse or otherwise overlay a respective portion of the OD 102, which forms the conductive channel of a corresponding transistor, with other non-overlaid portions of the OD 102 each formed as a source/drain structure of the corresponding transistor. Each gate of layout 400B can be formed or disposed across different cell rows or transistors (e.g., the second lateral direction, shown as vertically). For example, the gate A1 can be formed for the transistor 401A and transistor 401E, the gate A2 can be formed for the transistor 401B and the transistor 401F, the gate B1 can be formed for the transistor 401C and transistor 401G, and the gate B2 can be formed for the transistor 401D and the transistor 401H, at respective portions of the OD 102.

Various interconnect structures can be disposed above and connected to the portions of the OD 102 (or the source/drain structures) or the gate structures 104 (e.g., gates A1, A2, B1, or B2). For example, above the portions of the OD 102 (or the source/drain structures), respective interconnect structures can be formed, such as MD 106A above the source/drain structure 402A (e.g., OD portion 402A) and MD 106B above the source/drain structure 402B (e.g., OD portion 402B), among other MDs 106. Other interconnect structures can be disposed above the one or more MDs 106 and gate structures 104, such as MOs 112 are disposed above one or more MDs 106 and gate structures 104, and M1s 116 are disposed above one or more MOs 112. These interconnect structures above the MDs 106 or the gate structures 104 can be in (e.g., electrical) connection through a respective via structure, such as VD 110, VO 114, VD2 128, or VG 126.

In layout 400B, to minimize the effect of capacitive coupling between the MD 106A (e.g., above the common node C1) and the gate A1 and/or between the MD 106A and the gate A2, the isolation layer 118A is interposed between the MD 106A and the source/drain structure 402A. Further, to minimize the effect of capacitive coupling between the MD 106B (e.g., above the common node C2) and the gate B1 and/or between the MD 106B and the gate B2, the isolation layer 118B is interposed between the MD 106B and the source/drain structure 402B. The one or more isolation layers 118 can be disposed above and fully overlays the respective OD portions (e.g., OD portions 402A and/or 402B). As such, the MD 106A and MD 106B are electrically isolated from the OD portions 402A and 402B.

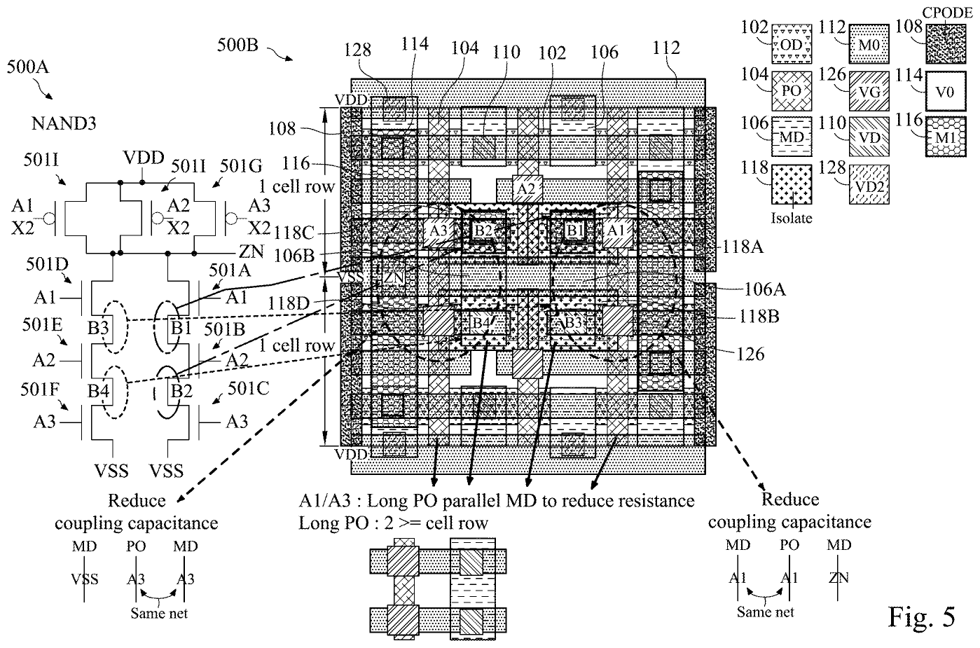

Referring now to FIG. 5, a circuit diagram of an example circuit 500A and a corresponding layout design 500B of a portion of the example circuit 500A are depicted, in accordance with various embodiments. The circuit 500A and the layout design 500B can correspond to a NAND3 device. One or more structures, formations, or dispositions of NAND3 can be described similarly to the semiconductor device of FIGS. 1-4, for example. The circuit 500A includes a first transistor 501A, a second transistor 501B, a third transistor 501C, a fourth transistor 501D, a fifth transistor 501E, a sixth transistor 501F, a seventh transistor 501G, an eighth transistor 501H, and a ninth transistor 5051, connected to each other either in parallel or in series. For example, the first, second, and third transistors 501A to 501C can be connected in series, and the fourth, fifth, and sixth transistors 501D to 501F can be connected in series. In this example, transistors 501A and 501B share a first common node (B1), transistors 501B and 501C share a second common node (B2), transistors 501D and 501E share a third common node (B3), and transistors 501E and 501F share a fourth common node (B4).

As shown in FIG. 5, the layout 500B includes one or more patterns (e.g., forming or defining OD 102, PO 104, MD 106, etc.) similar to one or more patterns associated with the layouts of FIGS. 1-4. In various embodiments, the layout 500B includes at least three gate structures 104, such as gates A1, A2, and A3. The gates A1, A2, and A3 can traverse or otherwise overlay a respective portion of the OD 102, which forms the conductive channel of a corresponding transistor, with other non-overlaid portions of the OD 102 each formed as a source/drain structure of the corresponding transistor. Each gate of layout 500B can be formed or disposed across different cell rows or transistors (e.g., the second lateral direction, shown as vertically). For example, the gate A1 can be formed for the transistors 501A, 501D, and 501I, the gate A2 can be formed for the transistors 501B, 501E, and 501H, and gate A3 can be formed for the transistors 501C, 501F, and 501G, at respective portions of the OD 102.

Various interconnect structures can be disposed above and connected to the portions of the OD 102 (or the source/drain structures) or the gate structures 104 (e.g., gates A1, A2, or A3). For example, above the portions of the OD 102 (or the source/drain structures), respective interconnect structures can be formed, such as MD 106A above the source/drain B1 and source/drain B3 and MD 106B above the source/drain B2 and source/drain B4. The MDs 106 may be a long MD extending across two or more cell rows. The long PO parallel MD can reduce the resistance and stabilize sensitive signals. Other interconnect structures can be disposed above the one or more MDs 106 and gate structures 104. For instance, MOs 112 are disposed above one or more MDs 106 and gate structures 104, and M1s 116 are disposed above one or more MOs 112. These interconnect structures above the MDs 106 or the gate structures 104 can be in (e.g., electrical) connection through a respective via structure, such as VD 110, VO 114, VD2 128, or VG 126.

In layout 500B, to minimize the effect of capacitive coupling between the MD 106A (e.g., above the common nodes B1 and/or B3) and the gate A1 and/or between the MD 106A and the gate A2, the isolation layer 118A is interposed between at least a portion of the MD 106A and the source/drain B1 and/or the isolation layer 118B is interposed between at least another portion of the MD 106A and the source/drain B3. Further, to minimize the effect of capacitive coupling between the MD 106B (e.g., above the common nodes B2 and/or B4) and the gate A2 and/or between the MD 106B and the gate A3, the isolation layer 118C is interposed between the MD 106B and the source/drain B2 and/or the isolation layer 118D is interposed between the MD 106B and the source/drain B4. The one or more isolation layers 118 can be disposed above and fully overlays the respective OD portions (e.g., source/drain B1, B2, B3, and/or B4). In some cases, one or more isolation layers 118 can be disposed below and fully underlays the respective MDs 106 (e.g., MD 106A and/or MD 106B). As such, the MD 106A and MD 106B are electrically isolated from the OD portions associated with common nodes B1 to B4.

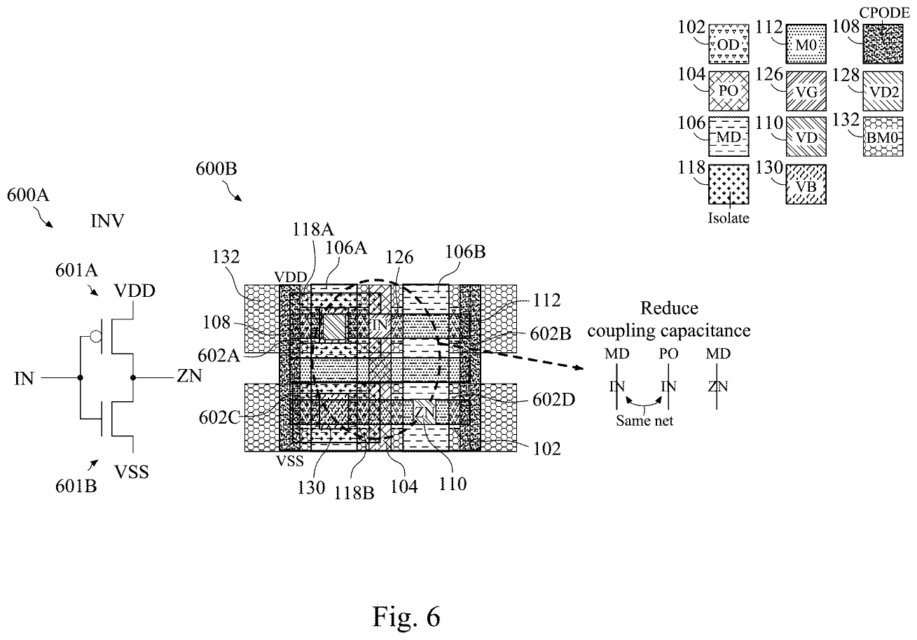

Referring to FIG. 6, a circuit diagram of an example circuit 600A and a corresponding layout design 600B of a portion of the example circuit 600A are depicted, in accordance with various embodiments. The circuit 600A and the layout design 600B can correspond to an inverter device. One or more structures, formations, or dispositions of the inverter can be described similarly to at least one of the semiconductor device of FIGS. 1-5, for example. The circuit 600A includes a first transistor 601A, and a second transistor 601B.

As shown in FIG. 6, the layout 600B includes one or more patterns (e.g., forming or defining OD 102, PO 104, MD 106, etc.) similar to one or more patterns associated with the layouts of FIGS. 1-5. In various embodiments, the layout 600B includes one gate structure 104. The gate structure 104 can traverse or otherwise overlay a respective portion of the OD 102, which forms the conductive channel of a corresponding transistor, with other non-overlaid portions of the OD 102 each formed as a source/drain structure of the corresponding transistor. The gate structure 104 of layout 600B can be formed or disposed across different cell rows or transistors (e.g., the second lateral direction, shown as vertically). For example, the gate structure 104 can be formed for the first transistor 601A and the second transistor 601B, at respective portions of the OD 102.

Various interconnect structures can be disposed above and connected to the portions of the OD 102 (or the source/drain structures) or the gate structure 104. For example, above the portions of the OD 102 (or the source/drain structures), respective interconnect structures can be formed, such as MD 106A above the source/drain structure 602A and source/drain structure 602C, and MD 106B above the source/drain structure 602B and source/drain structure 602D. Other interconnect structures can be disposed above the one or more MDs 106 and gate structures 104. For instance, MOs 112 are disposed above one or more MDs 106 and gate structures 104. These interconnect structures above the MDs 106 or the gate structures 104 can be in (e.g., electrical) connection through a respective via structure, such as VD 110, VD2 128, or VG 126. In some implementations, various interconnect structures can be disposed below the substrate (e.g., as described in conjunction with the semiconductor devices 200C and 200D of FIG. 2). For example, the one or more interconnect structures (e.g., additionally or alternatively to front side interconnect structures of the MDs 106 or the gate structure 104) can be disposed below the substrate. For instance, BMOs 132 are disposed below the OD 102 extending in a first lateral direction (e.g., shown as horizontally in FIG. 6). The BMOs 132 can be connected to the respective MDs 106 through VB 130.

In layout 600B, to minimize the effect of capacitive coupling between the MD 106A (e.g., above the source/drain structure 602A and source/drain structure 602C) and the gate structure 104, the isolation layer 118A is interposed between at least a portion of the MD 106A and the source/drain 602A and/or the isolation layer 118B is interposed between at least another portion of the MD 106A and the source/drain 602B. The one or more isolation layers 118 can be disposed above and fully overlays the respective OD portions (e.g., source/drain 602A and/or source/drain 602B). In some cases, the one or more isolation layers 118 can be merged or combined into a single isolation layer 118 extending across any lateral direction (e.g., the first and/or second lateral direction). As such, the MD 106A is electrically isolated from the portions of the OD 102, such as isolated from the source/drain 602A and source/drain 602B.

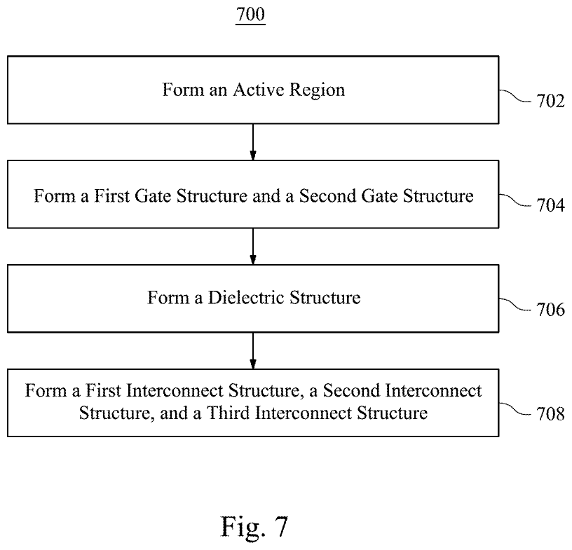

FIG. 7 depicts a flow diagram of a method 700 for forming a semiconductor device including a dielectric structure. It is understood that additional operations may be performed before, during, and/or after the method 700 depicted in FIG. 7. In some implementations, the method 700 is usable to form a semiconductor device, according to various layout designs as disclosed herein. Additional or alternative operations to the method 700 for forming a semiconductor device can be described in conjunction with at least one of FIGS. 1-6. For instance, the example operations of method 700 may be described in conjunction with at least one of FIGS. 1-2.

In operation 702 of method 700, an active region (e.g., OD 102) of the semiconductor device can be formed. The active region can be formed over a substrate (e.g., on the front side of the substrate). The active region can extend along a first lateral direction (e.g., shown as horizontally in FIGS. 1-2). The active region can be disposed next to or positioned between one or more power rails, output nodes, or power sources (e.g., CPODE 108).

In operation 704 of method 700, a first gate structure (e.g., PO) and a second gate structure can be formed. The first gate structure and the second gate structure can each extend along a second lateral direction perpendicular to the first lateral direction, such as in the vertical direction as shown in at least FIGS. 1-2. The first and second gate structures can extend across at least the active region. In some cases, the first and/or second gate structures can extend across multiple active regions.

The active regions can include various portions, such as defined by at least the gate structure(s) formed on the active region. For example, the first gate structure and the second gate structure can separate the active region into at least three portions (e.g., a first portion, a second portion, and a third portion). The first gate structure can be positioned between the first portion and the second portion of the active region. The second gate structure can be positioned between the first portion and the third portion of the active region. In this case, the first portion can represent the portion of the active region between the two gate structures of the transistors (e.g., the middle portion). The second portion can be disposed opposite the first gate structure from the first portion along the first lateral direction. The third portion can be disposed opposite the second gate structure from the first portion of the active region along the first lateral direction.

Various source/drain structures (e.g., EPIs) can be formed within at least one of the portions of the active regions. For example, a first source/drain structure of a first transistor can be formed or disposed in the second portion of the active region, and a second source/drain structure of the first transistor can be disposed in the first portion of the active region. The first and second source/drain structures can be disposed on opposite sides of the first gate structure, respectively.

Further, a third source/drain structure of a second transistor can be disposed in the first portion of the active region, and a fourth source/drain structure of the second transistor can be disposed in the third portion of the active region. The third and fourth source/drain structures can be disposed on opposite sides of the second gate structure, respectively. The second source/drain structure and the third source/drain structure can merge as a common source/drain structure. Hence, the first portion of the active region can include or represent the common source/drain structure between the two transistors, the second portion can represent the first source/drain structure, and the third portion can represent the fourth source/drain structure.

In operation 706 of method 700, a dielectric structure (e.g., isolation layer) can be formed. The dielectric structure can be formed overlaying the first portion of the active region (or the common source/drain structure) that is interposed between the first and second gate structures. The dielectric structure can be configured to electrically isolate materials, structures, or components on opposite sides of the dielectric structure.

In operation 708 of method 700, a first interconnect structure, a second interconnect structure, and a third interconnect structure (e.g., MDs) can be formed. The first to third interconnect structures can be formed over or disposed above the first portion, the second portion, and the third portion of the active region, respectively. In this example, the dielectric structure can be interposed between the first portion of the active region (or the common source/drain structure) and the first interconnect structure. The dielectric structure may be configured to electrically isolate the first portion of the active region and/or the common source/drain structure from the first interconnect structure. The second interconnect structure can be disposed above the first source/drain structure, and the third interconnect structure can be diposed above the fourth source/drain structure. The first to third interconnect structures can all extend along the second lateral direction on the front side of the substrate (e.g., above the active region). In some cases, the first to third interconnect structures may extend along the first lateral direction, if the active region extends along the second lateral direction.

Further, each of the interconnect structures (e.g., the first, second, or third interconnect structure) can be electrically coupled to a respective fourth interconnect structure (e.g., M0) formed on the front side. For example, one or more via structures (e.g., at least one of VD, VD2, VG, VB, etc.) can be formed and connected to at least the first interconnect structure, the second interconnect structure, or the third interconnect structures, among others. The fourth interconnect structure can be formed connected to the respective via structure. The fourth interconnect structure can extend along the first lateral direction (or in a direction similar to the active region). In some cases, the fourth interconnect structure can be configured at a power supply voltage or a fixed voltage (e.g., CPODE). The via structure can provide an electrical connection between the respective interconnect structure to at least the fourth interconnect structure. Additional interconnect structures can be formed above using similar operations, such as forming another via structure above one of the interconnect structures for electrical connection to a different interconnect structure formed above the via structure.

The first and/or second gate structures can be connected to the fourth interconnect structure (or other interconnect structures formed above the respective gate structure) through a via structure. In some implementations, the first interconnect structure isolated from the common source/drain structure can be configured at a floating voltage. In some implementations, the first interconnect structure can be configured at a first voltage (e.g., a predetermined voltage level) identical or similar to a second voltage provided to either the first gate structure or the second gate structure.

In some implementations, the second interconnect structure can be electrically connected to the first source/drain structure, and the third interconnect structure can be electrically connected to the fourth source/drain structure, as the dielectric structure is not interposed between the second or third interconnect structures and the respective source/drain structure. Each of the third interconnect structure and fourth interconnect structure can be electrically coupled to a fifth interconnect structure (e.g., formed on a front side of the substrate where the first and second transistors are formed) through a via structure. The fifth interconnect structure can be configured as an output node or a power rail (e.g., CPODE).

In some cases, the fifth interconnect structure can correspond to the fourth interconnect structure, such that the fourth interconnect structure is configured as the output node or the power rail. In some other cases, the fourth interconnect structure may not correspond to the fifth interconnect structure, such as configured as a different output node, a different power rail, among other features or functions. In some implementations, the fifth interconnect structure can refer to another interconnect structure formed above the fourth interconnect structure, such as M1 above M0.

In some implementations, a second dielectric structure can be interposed between the third interconnect structure and the fourth source/drain structure or the third portion of the active region. Multiple dielectric structures can be implemented in the semiconductor device. In this case, the second interconnect structure can be electrically connected to the first source/drain structure and the third interconnect structure can be electrically isolated from (e.g., not in electrical contact with) the fourth source/drain structure.

In some implementations, one or more interconnect structures can be formed on the backside of the substrate or the active region. For example, a sixth interconnect structure can be formed on the backside of the substrate configured as an output node or a power rail (e.g., supplying a predetermined voltage to the interconnect structure(s)). The backside of the substrate can refer to the side opposite to where the first and second gate structures and the first to third interconnect structures are formed. The substrate can be where the first and second transistors are formed. The third interconnect structure (or the first or the second interconnect structure) can be electrically coupled to the sixth interconnect structure (or other interconnect structures on the backside of the substrate) through a via structure, which can also be formed on the backside between the substrate and the sixth interconnect structure. In some implementations, the first to third interconnect structures can be electrically coupled to one or more interconnect structures formed on the backside of the substrate.

In one aspect of the present disclosure, a semiconductor device is disclosed. The semiconductor device includes a first source/drain structure and a second source/drain structure of a first transistor. The semiconductor device includes a third source/drain structure and a fourth source/drain structure of a second transistor. The second source/drain structure and the third source/drain structure can merge as a common source/drain structure. The semiconductor device includes a first interconnect structure extending along a first lateral direction and disposed above the common source/drain structure. The semiconductor device includes a first dielectric structure interposed between the first interconnect structure and the common source/drain structure.

In another aspect of the present disclosure, a semiconductor device is disclosed. The semiconductor device includes an active region formed on a front side of a substrate and extending along a first lateral direction. The semiconductor device includes a first gate structure extending along a second lateral direction and traversing across the active region. The semiconductor device includes a second gate structure extending along the second lateral direction and traversing across the active region. The semiconductor device includes a first interconnect structure extending along the second lateral direction and disposed between the first gate structure and the second gate structure. The semiconductor device includes a first dielectric structure vertically interposed between the first interconnect structure and a first portion of the active region laterally interposed between the first and second gate structures. The first portion of the active region can be electrically isolated from the first interconnect structure by the first dielectric structure

In yet another aspect of the present disclosure, a method for fabricating semiconductor devices is disclosed. The method includes forming an active region over a substrate, wherein the active region extends along a first lateral direction. The method includes forming a first gate structure and a second gate structure. The first gate structure and second gate structure can each extend along a second lateral direction perpendicular to the first lateral direction. The method includes forming a dielectric structure overlaying a first portion of the active region that is interposed between the first and second gate structures. The method includes forming a first interconnect structure, a second interconnect structure, and a third interconnect structure over the first portion, a second portion, and a third portion of the active region, respectively, with the dielectric structure interposed between the first portion of the active region and the first interconnect structure. The first to third interconnect structures can all extend along the second lateral direction.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain structure and a second source/drain structure of a first transistor;
a third source/drain structure and a fourth source/drain structure of a second transistor, wherein the second source/drain structure and the third source/drain structure merge as a common source/drain structure;
a first interconnect structure extending along a first lateral direction and disposed above the common source/drain structure; and
a first dielectric structure interposed between the first interconnect structure and the common source/drain structure.

2. The semiconductor device of claim 1, wherein the first dielectric structure is configured to electrically isolate the common source/drain structure from the first interconnect structure.

3. The semiconductor device of claim 1, wherein the first interconnect structure is configured at a floating voltage.

4. The semiconductor device of claim 1, further comprising:
a second interconnect structure extending along a second lateral direction perpendicular to the first lateral direction; and
a via structure electrically connecting the first interconnect structure to the second interconnect structure.

5. The semiconductor device of claim 4, wherein the second interconnect structure is configured at a power supply voltage or a fixed voltage.

6. The semiconductor device of claim 1, further comprising:
a first gate structure of the first transistor that extends along the first lateral direction, wherein the first source/drain structure and second source/drain structure are disposed on opposite sides of the first gate structure, respectively; and
a second gate structure of the second transistor that extends along the first lateral direction, wherein the third source/drain structure and fourth source/drain structure are disposed on opposite sides of the second gate structure, respectively.

7. The semiconductor device of claim 6, wherein the first interconnect structure is configured at a first voltage identical to a second voltage provided to either the first gate structure or the second gate structure.

8. The semiconductor device of claim 1, further comprising:
a third interconnect structure extending along the first lateral direction and disposed above the first source/drain structure; and
a fourth interconnect structure extending along the first lateral direction, and disposed above the fourth source/drain structure.

9. The semiconductor device of claim 8, wherein the third interconnect structure is electrically connected to the first source/drain structure and the fourth interconnect structure is electrically connected to the fourth source/drain structure; wherein each of the third interconnect structure and fourth interconnect structure is electrically coupled to a fifth interconnect structure that is configured as an output node or a power rail; and wherein the fifth interconnect structure is formed on a front side of a substrate where the first and second transistors are formed.

10. The semiconductor device of claim 8, further comprising:
a second dielectric structure interposed between the fourth interconnect structure and the fourth source/drain structure;
wherein the third interconnect structure is electrically connected to the first source/drain structure and the fourth interconnect structure is electrically isolated from the fourth source/drain structure;
wherein the fourth source/drain structure is electrically coupled to a sixth interconnect structure that is configured as an output node or a power rail; and
wherein the sixth interconnect structure is formed on a backside of a substrate where the first and second transistors are formed.

11. A semiconductor device, comprising:
an active region formed on a front side of a substrate and extending along a first lateral direction;
a first gate structure extending along a second lateral direction and traversing across the active region;
a second gate structure extending along the second lateral direction and traversing across the active region;
a first interconnect structure extending along the second lateral direction and disposed between the first gate structure and the second gate structure; and
a first dielectric structure vertically interposed between the first interconnect structure and a first portion of the active region laterally interposed between the first and second gate structures;
wherein the first portion of the active region is electrically isolated from the first interconnect structure by the first dielectric structure.

12. The semiconductor device of claim 11, further comprising:
a second interconnect structure extending along the second lateral direction and disposed above a second portion of the active region on the front side, wherein the second portion of the active region is disposed opposite the first gate structure from the first portion of the active region along the first lateral direction; and
a third interconnect structure extending along the second lateral direction and disposed above a third portion of the active region on the front side, wherein the third portion of the active region is disposed opposite the second gate structure from the first portion of the active region along the first lateral direction.

13. The semiconductor device of claim 12, wherein the second interconnect structure is in electrical contact with the second portion of the active region, and the third interconnect structure is in electrical contact with the third portion of the active region.

14. The semiconductor device of claim 13, wherein each of the second interconnect structure and the third interconnect structure is electrically coupled to a respective fourth interconnect structure formed on the front side.

15. The semiconductor device of claim 14, wherein the fourth interconnect structure is configured as an output node or a power rail.

16. The semiconductor device of claim 12, wherein the second interconnect structure is in electrical contact with the second portion of the active region, and the third interconnect structure is not in electrical contact with the third portion of the active region.

17. The semiconductor device of claim 16, wherein the third interconnect structure is electrically coupled to a fifth interconnect structure formed on a backside of the substrate.

18. A method for fabricating semiconductor devices, comprising:
forming an active region over a substrate, wherein the active region extends along a first lateral direction;
forming a first gate structure and a second gate structure, wherein the first gate structure and second gate structure each extend along a second lateral direction perpendicular to the first lateral direction;
forming a dielectric structure overlaying a first portion of the active region that is interposed between the first and second gate structures; and
forming a first interconnect structure, a second interconnect structure, and a third interconnect structure over the first portion, a second portion, and a third portion of the active region, respectively, with the dielectric structure interposed between the first portion of the active region and the first interconnect structure, wherein the first to third interconnect structures all extend along the second lateral direction.

19. The method of claim 18, wherein the dielectric structure is configured to electrically isolate the first portion of the active region from the first interconnect structure.

20. The method of claim 18, further comprising:
forming a via structure connected to the first interconnect structure; and
forming a fourth interconnect structure connected to the via structures, wherein the fourth interconnect structure extends along the first lateral direction and is configured at a power supply voltage or a fixed voltage.
